(19) United States
(12) Patent Application Publication
(10) Pub. No.: US 2010/0133597 A1
(43) Pub. Date: Jun. 3, 2010

(54) SEMICONDUCTOR MEMORY DEVICE AND MANUFACTURING METHOD THEREOF

(75) Inventors: Takayuki OKADA, Kawasaki-shi (JP); Hiroyuki KANAYA, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/560,063

(22) Filed: Sep. 15, 2009

(30) Foreign Application Priority Data
Dec. 1, 2008 (JP) 2008-306317

(51) Int. Cl. H01L 29/82; H01L 21/28

(52) U.S. Cl. 257/295; 438/3; 257/E29.323; 257/E27.084; 257/E21.158

(57) ABSTRACT

A semiconductor memory device including a ferroelectric capacitor, the ferroelectric capacitor includes a lower electrode having a plurality of protrusions; a ferroelectric film on the lower electrode, the ferroelectric film having a plurality of protrusions engaging with the protrusions of the lower electrode; and an upper electrode on the ferroelectric film, the upper electrode having a plurality of protrusions engaging with the protrusions of the lower electrode.

### CROSS-REFERENCE TO RELATED APPLICATION

This application is based upon and claims the benefit of priority from the prior Japanese Patent Applications No. 2008-306317, filed on Dec. 1, 2008, the entire contents of which are incorporated herein by reference.

### BACKGROUND OF THE INVENTION

1. Field of the Invention

The present invention relates to semiconductor memory device and manufacturing method thereof.

2. Related Art

According to downscaling of ferroelectric memories, a signal amount between data “1” and data “0” becomes more decreased. Increasing an area of opposing electrodes of a ferroelectric capacitor is considered to be a measure to increase the signal amount of the ferroelectric memory.

JP-A 2000-357783 (KOKAI) and JP-A 2006-190765 (KOKAI) disclose a lower electrode with irregularities obtained by forming a conductive film and performing a thermal process upon the film. However, the film forming step and the thermal process step for the lower electrode are difficult to control the irregularities.

### SUMMARY OF THE INVENTION

A semiconductor memory device comprising a ferroelectric capacitor according to an embodiment of the present invention, the ferroelectric capacitor comprises: a lower electrode having a plurality of protrusions; a ferroelectric film on the lower electrode, the ferroelectric film having a plurality of protrusions engaging with the protrusions of the lower electrode; and an upper electrode on the ferroelectric film, the upper electrode having a plurality of protrusions engaging with the protrusions of the lower electrode.

A manufacturing method of a semiconductor memory device according to an embodiment of the present invention comprises: depositing a material for a lower electrode above a semiconductor substrate; forming a sacrificial layer with protrusions on the material for the lower electrode; etching the sacrificial layer and the material for the lower electrode to transfer a surface profile of protrusions of the sacrificial layer to the lower electrode; depositing a ferroelectric film on the lower electrode; depositing an upper electrode on the ferroelectric film; and patterning the upper electrode, the ferroelectric film, and the lower electrode into a pattern of a ferroelectric capacitor.

A manufacturing method of a semiconductor memory device according to an embodiment of the present invention comprises: depositing a material for a first lower electrode above a semiconductor substrate; forming a sacrificial layer with discontinuous protrusions on the material for the first lower electrode; depositing a material for a second lower electrode on the sacrificial layer and the material for the first lower electrode; depositing a ferroelectric film on the second lower electrode; depositing an upper electrode on the ferroelectric film; and patterning the upper electrode, the ferroelectric film, and the lower electrode into a pattern of a ferroelectric capacitor.

A manufacturing method of a semiconductor memory device according to an embodiment of the present invention comprises: depositing a material for a first lower electrode above a semiconductor substrate; forming a sacrificial layer with discontinuous protrusions on the material for the first lower electrode; a part of the first lower electrode is etched by using the sacrificial layer as a mask in order to form a groove on a top of the first lower electrode; removing the sacrificial layer; depositing a material for a second lower electrode on the material for the first lower electrode; depositing a ferroelectric film on the second lower electrode; depositing an upper electrode on the ferroelectric film; and patterning the upper electrode, the ferroelectric film, and the lower electrode into a pattern of a ferroelectric capacitor.

### BRIEF DESCRIPTION OF THE DRAWINGS

FIG. 1 is a cross-sectional view showing a configuration of a ferroelectric capacitor according to a first embodiment of the present invention;

FIGS. 2 to 7 are cross-sectional views showing a manufacturing method of the ferroelectric capacitor according to the first embodiment;

FIG. 8 is a plan view showing a pattern of protrusions 20 of the lower electrode LE, the ferroelectric film FE or the upper electrode UE according to the first embodiment;

FIG. 9 is a plan view of another pattern of the protrusions 20;

FIGS. 10A, 10B, 11A and 11B are perspective views of the protrusions 20;

FIGS. 12 to 15 are cross-sectional views showing a manufacturing method of the ferroelectric capacitor according to a second embodiment;

FIGS. 16 and 17 are cross-sectional views showing a manufacturing method of the ferroelectric capacitor according to a third embodiment;

FIGS. 18 and 19 are cross-sectional views showing a manufacturing method of the ferroelectric capacitor according to a fourth embodiment;

FIG. 20 is a cross-sectional view showing a manufacturing method of the ferroelectric capacitor according to a fifth embodiment;

FIG. 21 is a cross-sectional view of a ferroelectric capacitor with a PZT film formed by sputtering; and

FIG. 22 is a cross-sectional view of a ferroelectric capacitor with a PZT film formed by MOCVD.

### DETAILED DESCRIPTION OF THE INVENTION

Embodiments of the present invention will be explained below in detail with reference to the accompanying drawings. Note that the invention is not limited thereto.

### First embodiment

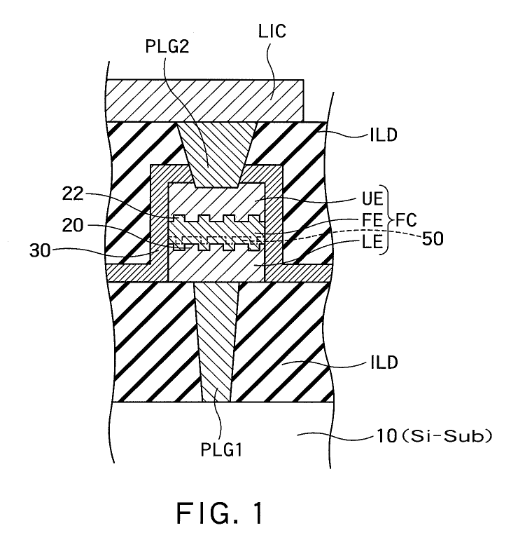

FIG. 1 is a cross-sectional view showing a configuration of a ferroelectric capacitor according to a first embodiment of the present invention. In FIG. 1, only the ferroelectric capacitor is shown and a cell transistor is omitted.

A ferroelectric memory according to the first embodiment is formed on a silicon substrate 10. A cell transistor (not shown in FIG. 1) is provided on the silicon substrate 10. An interlayer dielectric film ILD is provided on the silicon substrate 10 so as to cover the cell transistor. A contact plug PLG1 passes through the interlayer dielectric film ILD to reach the silicon substrate 10. The contact plug PLG1 is formed so as to be connected to either a source diffusion layer or a drain diffusion layer of the cell transistor.

A ferroelectric capacitor FC is provided on the contact plug PLG1 and the interlayer dielectric film ILD. In this way, the ferroelectric capacitor FC is provided on the contact plug PLG1 and this contact plug PLG1 connects between a lower electrode LE and the cell transistor. This is called “COP (Capacitor On Plug) structure”.

The ferroelectric capacitor FC includes the lower electrode LE, a ferroelectric film FE, and an upper electrode UE. A hydrogen barrier film 30 is formed on top and side surfaces of the ferroelectric capacitor FC. An interlayer dielectric film ILD is provided on the hydrogen barrier film 30 so as to surround the periphery of the ferroelectric capacitor FC.

The hydrogen barrier film 30 on the upper electrode UE of the ferroelectric capacitor FC is partially open and a contact plug PLG2 is loaded in the opening. Thus, the contact plug PLG2 is connected to the upper electrode UE.

A local interconnection LIC is formed on the interlayer dielectric film ILD and the contact plug PLG2. The local interconnection LIC is electrically connected via the contact plug PLG2 to the upper electrode UE. Further, the local interconnection LIC electrically connects upper electrodes UE of two ferroelectric capacitors adjacent to each other in a bit line direction to one of source and drain of the cell transistor. The contact plug PLG1 electrically connects the lower electrode LE to the other of source and drain of the cell transistor. As a result, “Series connected TC unit type ferroelectric RAM” can be configured. The “Series connected TC unit type ferroelectric RAM” consists of series connected memory cells each having a transistor having a source terminal and a drain terminal and a ferroelectric capacitor inbetween said two terminals. The first embodiment is not limited to the series connected TC unit type ferroelectric RAM and can be also applied to any ferroelectric memory utilizing ferroelectric capacitors.

In the first embodiment, the lower electrode LE is formed so as to have a plurality of protrusions 20. A bottom surface of the ferroelectric film FE has corresponding irregularities to engage with the protrusions 20 of the lower electrode LE. A top surface of the ferroelectric film FE is formed so as to have protrusions 22 like the surface of the lower electrode LE. Further, a bottom surface of the upper electrode UE has irregularities engaging with the protrusions 22 of the ferroelectric film FE.

Because the irregularities are provided in the ferroelectric capacitor FC, the area the lower electrode LE contacts the ferroelectric film FE and the area the upper electrode UE contacts the ferroelectric film FE are larger than cases of flat films. That is, a capacitance of the ferroelectric capacitor FC according to the first embodiment is larger than those of conventional ferroelectric capacitors. Thus, even if each memory cell in the ferroelectric memory is downscaled, the memory cell according to the first embodiment can ensure a large signal difference between data “1” and data “0”. Accordingly, controllability of the ferroelectric memory is improved.

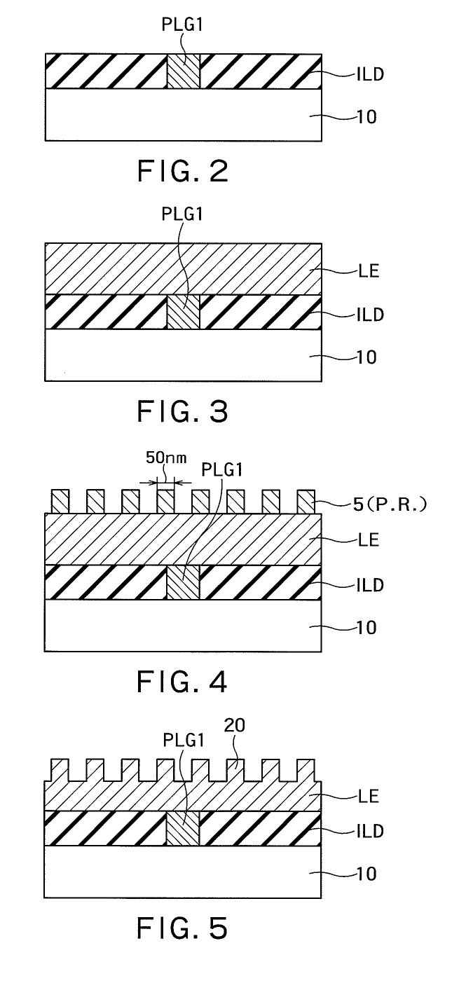

A manufacturing method of the ferroelectric capacitor according to the first embodiment is described with reference to FIGS. 2 to 7. Because FIGS. 2 to 7 schematically show the ferroelectric capacitor, its scale is different from that of FIG. 1 or the real one.

A cell transistor (not shown) is formed on the silicon substrate 10. A gate electrode of the cell transistor also serves as a word line WL. An interlayer dielectric film ILD is deposited on the silicon substrate 10 and the cell transistor. As shown in FIG. 2, the contact plug PLG1 is formed in the interlayer dielectric film ILD.

As shown in FIG. 3, the material for the lower electrode LE is deposited on the interlayer dielectric film ILD. The material for the lower electrode LE is a material made of Ti, TiN, TiAlN, Pt, Ir, IrO₂, SRO, Ru, or RuO₂, for example.

As shown in FIG. 4, a fine pattern of a photoresist 5 serving as a sacrificial layer is formed on the lower electrode LE by photolithography. According to this photolithography, for example, a pattern with protrusions with a width of about 50 nm can be formed on the lower electrode LE. By such photolithography, a pattern of irregularities can be formed in a ferroelectric capacitor. Reference numeral 5 can denote a sacrificial layer formed of other material instead of the photoresist.

The photoresist 5 and the top part of the lower electrode LE are etched by RIE (Reactive Ion Etching). Thus, as shown in FIG. 5, the surface pattern of the photoresist 5 is transferred to the lower electrode LE. The height of protrusion 20 of the lower electrode LE can be changed depending on the height of the remaining photoresist 5 during etching. The height of protrusion 20 of the lower electrode LE becomes the highest when etching is performed until all of the photoresist 5 is removed.

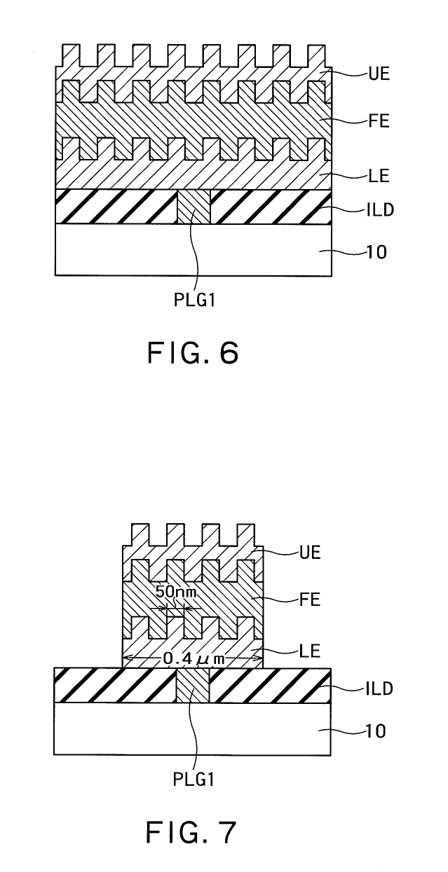

As shown in FIG. 6, the ferroelectric film FE is then deposited on the lower electrode LE. The material for the ferroelectric film FE is PZT(Pb(ZrₓTi₍₁₋ₓ₎)O₃), SBT(SrBi₂Ta₂O₉), or BLT((Bi,La)₄Ti₃O₁₂), for example. The surface of the ferroelectric film FE is formed so as to have irregularities like the surface pattern of the lower electrode LE. The upper electrode UE is further deposited on the ferroelectric film FE. The material for the upper electrode UE is Pt, Ir, IrO₂, SRO, Ru, or RuO₂, for example. The surface of the upper electrode UE is formed so as to have irregularities like the surface patterns of the lower electrode LE and the ferroelectric film FE.

As shown in FIG. 7, the upper electrode UE, the ferroelectric film FE, and the lower electrode LE are etched, so that the ferroelectric capacitor FC is formed. For example, the upper electrode UE, the ferroelectric film FE, and the lower electrode LE have a size of about 0.4 μm square and the protrusion has a width of about 50 nm.

The hydrogen barrier film 30 is then deposited on the top and side surfaces of the ferroelectric capacitor FC and the interlayer dielectric film ILD is deposited on the hydrogen barrier film 30 as shown in FIG. 1. The contact plug PLG2 reaching the upper electrode UE is formed. The local interconnection LIC is then formed on the contact plug PLG2. Further, an interlayer dielectric film and a bit line are formed. As a result, the ferroelectric memory according to the first embodiment is completed.

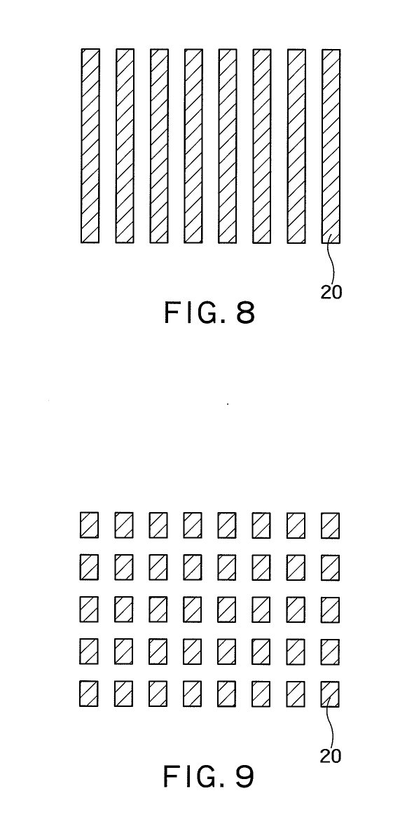

FIG. 8 is a plan view showing a pattern of protrusions 20 of the lower electrode LE, the ferroelectric film FE or the upper electrode UE according to the first embodiment. With reference to FIG. 8, the protrusions 20 are formed in stripes on the surface of the lower electrode LE. The surfaces or the bottom surfaces of the ferroelectric film FE and the upper electrode UE are formed in a stripe pattern according to the surface pattern of the lower electrode LE.

FIG. 9 is a plan view of another pattern of the protrusions 20. With reference to FIG. 9, the protrusions 20 are formed on the surface of the lower electrode LE like islands so as to constitute a matrix form. The surfaces or bottom surfaces of the ferroelectric film FE and the upper electrode UE are formed in a stripe pattern according to the surface pattern of the lower electrode LE.

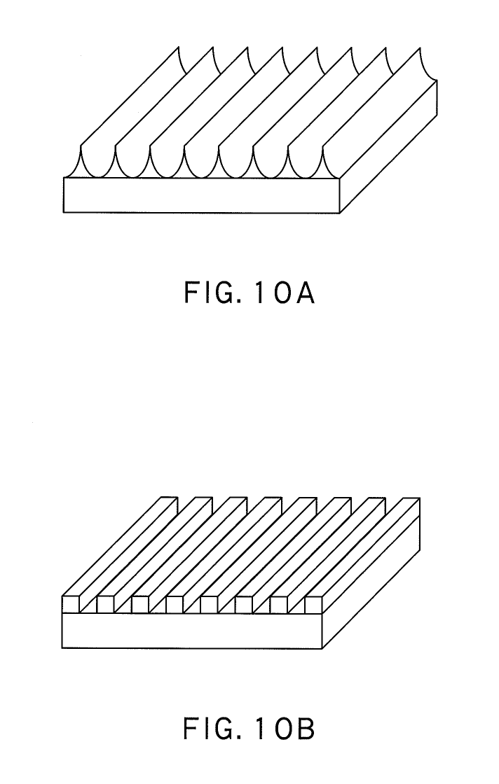

With reference to FIGS. 10A and 10B, the protrusions 20 are formed in stripes on the surface of the lower electrode LE. However, the shape of the protrusion 20 shown in FIG. 10A is different from that of the protrusion 20 shown in FIG. 10B.

With reference to FIG. 10A, a distal end of the protrusion 20 is fine and sharp. In this case, when the surface pattern of the photoresist 5 is transferred to the lower electrode LE, CDE (Chemical Dry Etching) or isotropic etching such as wet etching can be used.

With reference to FIG. 10B, the protrusion 20 is formed in a rectangular parallelepiped shape. In this case, when the surface pattern of the photoresist 5 is transferred to the lower electrode LE, anisotropic etching such as RIE can be used.

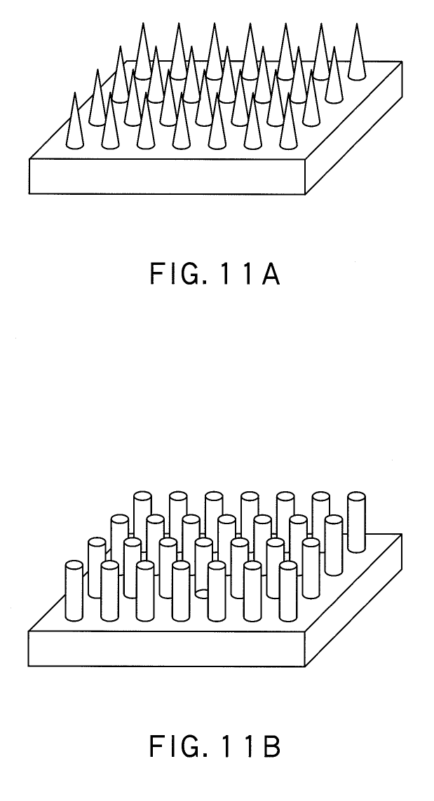

With reference to FIGS. 11A and 11B, the protrusions 20 are formed on the surface of the lower electrode LE like islands so as to constitute a matrix form. However, the shape of the protrusion 20 shown in FIG. 11A is different from that of the protrusion 20 shown in FIG. 11B.

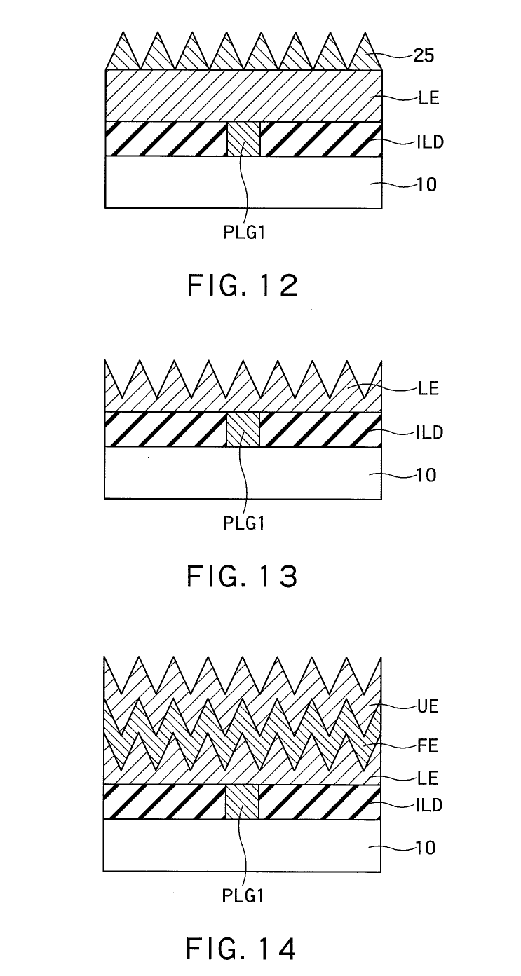

The protrusion 20 is formed in a cone shape with fine and sharp distal end in FIG. 12A. In this case, when the surface pattern of the photoresist 5 is transfer red to the lower electrode LE, CDE (Chemical Dry Etching) or isotropic etching such as wet etching can be used.

The protrusion 20 is formed in a cylindrical shape in FIG. 12B. In this case, when the surface pattern of the photoresist 5 is transferred to the lower electrode LE, anisotropic etching such as RIE can be used.

### Second Embodiment

According to a second embodiment of the present invention, a hard mask 25 is used as a sacrificial layer to form the protrusions 20 on the surface of the lower electrode LE as shown in FIG. 12. Other manufacturing steps in the second embodiment can be identical to those in the first embodiment.

The material for the hard mask 25 can be PZT(Pb(ZrₓTi₍₁₋ₓ₎)O₃), SBT(SrBi₂Ta₂O₉), or BLT((Bi,La)₄Ti₃O₁₂), for example. For example, when a lead zirconate titanate (PZT) film is deposited on a plane by MOCVD (Metalorganic Chemical Vapor Deposition) under a substrate temperature of 590 to 620° C., the height of the protrusion 20 formed of the PZT film is 80 to 120 nm. That is, when the above MOCVD is used, the hard mask 25 with the protrusions 20 can be formed on the flat lower electrode LE without using photolithography.

As shown in FIG. 13, the hard mask 25 and the top of the lower electrode LE are etched by RIE. Thus, the plane pattern of the hard mask 25 is transferred to the lower electrode LE.

The ferroelectric film FE is then deposited on the lower electrode LE as shown in FIG. 14. At this time, the surface of the ferroelectric film FE is formed so as to have irregularities like the surface pattern of the lower electrode LE. The upper electrode UE is further deposited on the ferroelectric film FE. The surface of the upper electrode UE is formed so as to have irregularities like the surface patterns of the lower electrode LE and the ferroelectric film FE.

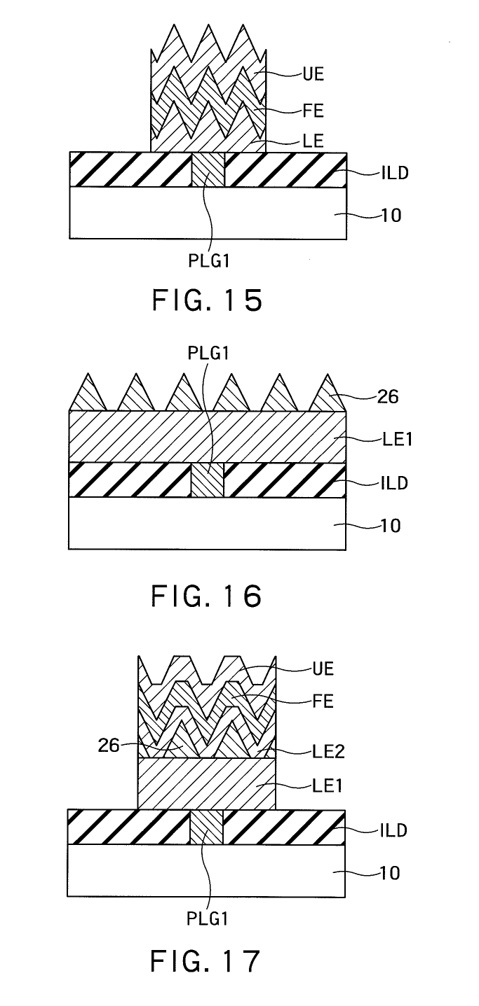

As shown in FIG. 15, the upper electrode UE, the ferroelectric film FE, and the lower electrode LE are etched, so that the ferroelectric capacitor FC is formed.

Thereafter, the hydrogen barrier film 30, the interlayer dielectric film ILD, the contact plug PLG2, the local interconnection LIC, and the bit line are formed similarly to the first embodiment. In this way, the ferroelectric memory of the second embodiment is completed.

In the second embodiment, similarly to the first embodiment, the lower electrode LE, the ferroelectric film FE, and the upper electrode UE are formed so as to have the protrusions 20. Because the ferroelectric capacitor FC is provided with irregularities, the second embodiment can achieve effects identical to those of the first embodiment.

The plane patterns shown in FIG. 8 to FIG. 11B can be applied to the second embodiment.

### Third Embodiment

The ferroelectric capacitor FC according to a third embodiment of the present invention comprises a sacrificial layer 26 formed of a ferroelectric material remaining in a lower electrode LE as shown in FIG. 17. More specifically, the ferroelectric capacitor FC includes a first lower electrode LE1 and a second lower electrode LE2 as the lower electrode LE. The sacrificial layer 26 is provided between the first lower electrode LE1 and the second lower electrode LE2. The sacrificial layer 26 is formed on the first lower electrode LE1 in a discontinuous manner and electrically connected to the first lower electrode LE1 and the second lower electrode LE2.

A manufacturing method according to the third embodiment is described next. After the steps shown in FIGS. 2 and 3, the sacrificial layer 26 is formed as discontinuous protrusions on the material for the first lower electrode LE1 as shown in FIG. 16. The material for the sacrificial layer 26 can be a ferroelectric material like the hard mask 25 in the second embodiment. The material for the sacrificial layer 26 can be metals, semiconductors, or insulators. After the material for the sacrificial layer 26 is deposited on the material for the first lower electrode LE1, the material is selectively etched in an anisotropic manner. Thus, the sacrificial layer 26 formed as discontinuous protrusions can be obtained.

As shown in FIG. 17, the second lower electrode LE2 is deposited on the first lower electrode LE1 and the sacrificial layer 26. At this time, the plane pattern of the second lower electrode LE2 is formed so as to have irregularities according to the plane pattern formed by the first lower electrode LE1 and the sacrificial layer 26. The material for the first and the second lower electrodes LE1 and LE2 can be the same as the one for the lower electrode LE in the first embodiment. The material for the second lower electrode LE2 can be the same as or different from the one for the first lower electrode LE1.

The ferroelectric film FE is then deposited on the lower electrode LE. The surface of the ferroelectric film FE is formed so as to have irregularities like the surface pattern of the lower electrode LE. The upper electrode UE is further deposited on the ferroelectric film FE. The surface of the upper electrode UE is formed so as to have irregularities like the surface patterns of the lower electrode LE and the ferroelectric film FE.

Subsequently, the upper electrode UE, the ferroelectric film FE, and the lower electrode LE are etched, so that the ferroelectric capacitor FC is formed.

Thereafter, the hydrogen barrier film 30, the interlayer dielectric film ILD, the contact plug PLG2, the local interconnection LIC, and the bit line are formed similarly to the first embodiment. In this way, the ferroelectric memory according to the third embodiment is completed.

In the third embodiment, similarly to the first embodiment, the lower electrodes LE1 and LE2, the ferroelectric film FE, and the upper electrode UE are formed so as to have a plurality of protrusions. By providing irregularities to the ferroelectric capacitor FC as described above, the third embodiment can achieve effects identical to those of the first embodiment.

The plane patterns shown in FIG. 8 to FIG. 11B can be applied to the third embodiment.

### Fourth Embodiment

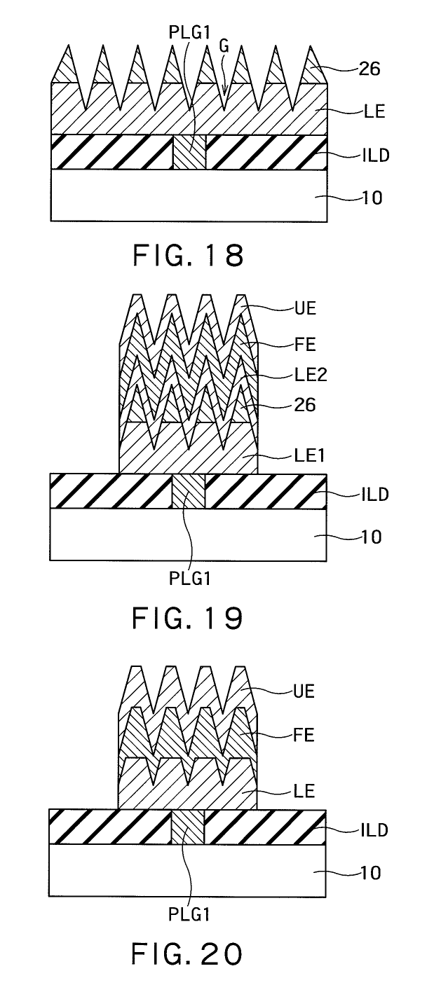

According to a fourth embodiment of the present invention, after the step shown in FIG. 16, the first lower electrode LE1 is partially etched by using the sacrificial layer 26 as a mask as shown in FIG. 18. Thus, the first lower electrode LE1 has grooves G as shown in FIG. 18.

The material for the second lower electrode LE2 is then deposited on the first lower electrode LE1 and the sacrificial layer 26 as shown in FIG. 19. At this time, the plane pattern of the second lower electrode LE2 is formed so as to have irregularities according to the plane pattern formed by the first lower electrode LE1 and the sacrificial layer 26.

The ferroelectric film FE is then deposited on the second lower electrode LE2. The surface of the ferroelectric film FE is formed so as to have irregularities like the surface pattern of the second lower electrode LE2. The upper electrode UE is further deposited on the ferroelectric film FE. The surface of the upper electrode UE is formed so as to have irregularities like the surface patterns of the lower electrodes LE1, LE2 and the ferroelectric film FE.

The upper electrode UE, the ferroelectric film FE, and the lower electrodes LE1 and LE2 are etched, so that the ferroelectric capacitor FC is formed.

Thereafter, the hydrogen barrier film 30, the interlayer dielectric film ILD, the contact plug PLG2, the local interconnection LIC, and the bit line are formed similarly to the first embodiment. In this way, the ferroelectric memory of the fourth embodiment is completed.

According to the fourth embodiment, the irregularities on the surfaces of the lower electrodes LE1 and LE2 are larger than those of the third embodiment. The surface area of the ferroelectric capacitor FC in the fourth embodiment is larger than the one in the third embodiment. Thus, a large signal amount can be kept even if further downscaling is performed in the fourth embodiment. In addition, the fourth embodiment can achieve effects identical to those of the first embodiment.

The plane patterns shown in FIG. 8 to FIG. 11B can be applied to the fourth embodiment.

### Fifth Embodiment

According to a fifth embodiment of the present invention, after the grooves G are formed in the lower electrode LE as shown in FIG. 18, the sacrificial layer 26 is removed. Thus, the lower electrode LE does not need to be divided into the first lower electrode LE1 and the second lower electrode LE2 in the fifth embodiment. After the sacrificial layer 26 is removed, the ferroelectric film FE is deposited on the lower electrode LE similarly to the fourth embodiment. The surface of the ferroelectric film FE is formed so as to have irregularities like the surface pattern of the lower electrode LE. The upper electrode UE is further deposited on the ferroelectric film FE. The surface of the upper electrode UE is formed so as to have irregularities like the surface patterns of the lower electrode LE and the ferroelectric film FE.

The upper electrode UE, the ferroelectric film FE, and the lower electrode LE are then etched, so that the ferroelectric capacitor FC is formed.

Thereafter, the hydrogen barrier film 30, the interlayer dielectric film ILD, the contact plug PLG2, the local interconnection LIC, and the bit line are formed similarly to the first embodiment. In this way, the ferroelectric memory according to the fifth embodiment is completed.

In the fifth embodiment, similarly to the first embodiment, the lower electrode LE, the ferroelectric film FE, and the upper electrode UE are formed so as to have irregularities. By providing irregularities to the ferroelectric capacitor FC as described above, the fifth embodiment can achieve effects identical to those of the first embodiment.

The plane patterns shown in FIG. 8 to FIG. 11B can be applied to the fifth embodiment.

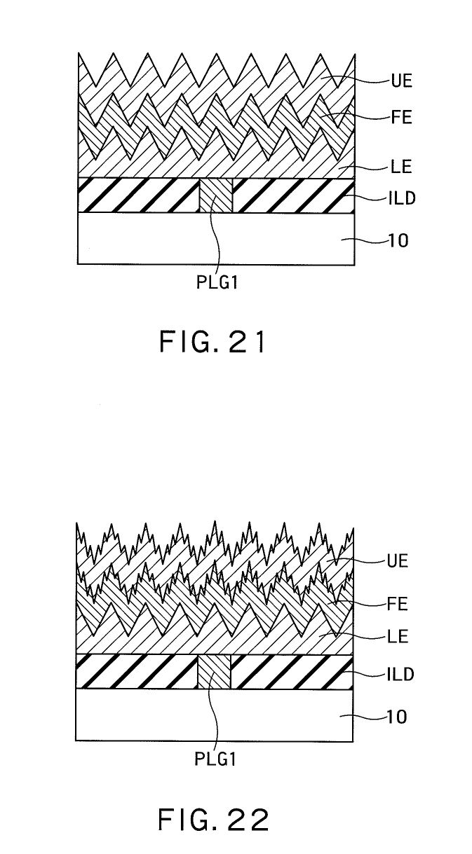

In the first to fifth embodiments, the ferroelectric film FE can be, for example, a PZT film formed by sputtering. In this case, the surface of the ferroelectric film FE is formed according to the surface of the lower electrode LE as shown in FIG. 21. FIG. 21 is a cross-sectional view of a ferroelectric capacitor with a PZT film formed by sputtering.

The ferroelectric film FE can be, for example, a PZT film formed using MOCVD under a substrate temperature of 590 to 620° C. In this case, the surface of the ferroelectric film FE has 80 to 120 nm of irregularities even if the film is deposited on a plane. When the ferroelectric film FE is deposited on the lower electrode LE, the surface of the ferroelectric film FE has larger irregularities than those of surface of the lower electrode LE as shown in FIG. 22. Thus, the surface area of the ferroelectric capacitor FC can be further increased. FIG. 22 is a cross-sectional view of a ferroelectric capacitor with a PZT film formed by MOCVD.

In the first to fifth embodiments, an additional electrode layer 50 can be formed as shown by a broken line in FIG. 1 after the lower electrode LE or the lower electrodes LE1 and LE2 are formed in order to form an excellent interface with the ferroelectric film FE.

1. A semiconductor memory device comprising a ferroelectric capacitor, the ferroelectric capacitor comprising:
a lower electrode comprising a plurality of protrusions;
a ferroelectric film on the lower electrode, the ferroelectric film comprising a plurality of protrusions configured to engage with the protrusions of the lower electrode; and
an upper electrode on the ferroelectric film, the upper electrode comprising a plurality of protrusions configured to engage with the protrusions of the lower electrode.

2. The device of claim 1, wherein the protrusions are on a surface of the lower electrode in stripes.

3. The device of claim 1, wherein the protrusions are island-shaped on the surface of the lower electrode.

4. The device of claim 1, wherein the protrusions are matrix-shaped on the surface of the lower electrode.

5. The device of claim 1 further comprising:
a cell transistor on a semiconductor substrate;
an interlayer dielectric film on the cell transistor; and
a contact plug through the interlayer dielectric film, configured to be connect to either a source or a drain of the cell transistor, wherein
the lower electrode, the ferroelectric film, and the upper electrode are on the interlayer dielectric film and the contact plug.

6. The device of claim 1 further comprising a sacrificial layer in the lower electrode and comprising a ferroelectric material, a metal, a semiconductor, or an insulator.

7. A manufacturing method of a semiconductor memory device comprising:
depositing a material for a lower electrode above a semiconductor substrate;
forming a sacrificial layer with protrusions on the material for the lower electrode;
etching the sacrificial layer and the material for the lower electrode in order to transfer a surface profile of protrusions of the sacrificial layer to the lower electrode;
depositing a ferroelectric film on the lower electrode;
depositing an upper electrode on the ferroelectric film; and
patterning the upper electrode, the ferroelectric film, and the lower electrode into a pattern of a ferroelectric capacitor.

8. A manufacturing method of a semiconductor memory device comprising:
depositing a material for a first lower electrode above a semiconductor substrate;
forming a sacrificial layer with discontinuous protrusions on the material for the first lower electrode;
depositing a material for a second lower electrode on the sacrificial layer and the material for the first lower electrode;
depositing a ferroelectric film on the second lower electrode;
depositing an upper electrode on the ferroelectric film; and
patterning the upper electrode, the ferroelectric film, and the lower electrode into a pattern of a ferroelectric capacitor.

9. The method of claim 8, wherein a part of the first lower electrode is etched using the sacrificial layer as a mask in order to form a groove on a top of the first lower electrode after the sacrificial layer is formed.

10. A manufacturing method of a semiconductor memory device comprising:
depositing a material for a first lower electrode above a semiconductor substrate;
forming a sacrificial layer with discontinuous protrusions on the material for the first lower electrode;
a part of the first lower electrode is etched by using the sacrificial layer as a mask in order to form a groove on a top of the first lower electrode;
removing the sacrificial layer;
depositing a material for a second lower electrode on the material for the first lower electrode;
depositing a ferroelectric film on the second lower electrode;
depositing an upper electrode on the ferroelectric film; and
patterning the upper electrode, the ferroelectric film, and the lower electrode into a pattern of a ferroelectric capacitor.

11. The method of claim 7, wherein the sacrificial layer is a ferroelectric film formed by Metal Organic Chemical Vapor Deposition (MO-CVD) method.

12. The method of claim 8, wherein the sacrificial layer is a ferroelectric film formed by MO-CVD method.

13. The method of claim 9, wherein the sacrificial layer is a ferroelectric film formed by MO-CVD method.

14. The method of claim 10, wherein the sacrificial layer is a ferroelectric film formed by MO-CVD method.
